(19) United States
(12) Patent Application Publication
(10) Pub. No.: US 2017/0207103 A1
(43) Pub. Date: Jul. 20, 2017

(54) GAS PHASE ETCH OF AMORPHOUS AND POLY-CRYSTALLINE SILICON FROM HIGH ASPECT RATIO FEATURES WITH HIGH SELECTIVITY TOWARDS VARIOUS FILMS

(71) Applicant: Tokyo Electron Limited, Tokyo (JP)

(72) Inventors: Subhadeep Kal, Albany, NY (US); Elliott Franke, Albany, NY (US); Akiteru Ko, Schenectady, NY (US); Aelan Mosden, Poughkeepsie, NY (US)

(21) Appl. No.: 15/405,977

(22) Filed: Jan. 13, 2017

Related U.S. Application Data
(60) Provisional application No. 62/278,932, filed on Jan. 14, 2016.

(51) Int. Cl. H01L 21/3213; H01L 21/321

(52) U.S. Cl. CPC H01L 21/32135; H01L 21/321

(57) ABSTRACT

A method for the dry removal of a material on a microelectronic workpiece is described. The method includes receiving a workpiece having a surface exposing a target layer composed of silicon selected from the group consisting of amorphous silicon (a-Si), polycrystalline silicon (poly-Si), and doped silicon that fills a trench or via within a retention layer, and selectively removing at least a portion of the target layer from the retention layer. The selective removal includes exposing the surface of the workpiece to a chemical environment containing N, H, and F at a first setpoint temperature to chemically alter a surface region of the target layer, and then, elevating the temperature of the workpiece to a second setpoint temperature to remove the chemically treated surface region of the target layer.

### CROSS-REFERENCE TO RELATED APPLICATIONS

This application is related to and claims priority to U.S. Provisional Patent Application No. 62/278,932, filed Jan. 14, 2016, the entire contents of which are herein incorporated by reference.

### FIELD OF INVENTION

The invention relates to a non-plasma, gas-phase etching of materials and structures on a substrate.

### DESCRIPTION OF RELATED ART

The need to remain competitive in cost and performance in the production of semiconductor devices elevates demand to continually increase the device density of integrated circuits. And, to achieve higher degrees of integration with the miniaturization in semiconductor integrated circuitry, robust methodologies are required to reduce the scale of the circuit pattern formed on the semiconductor substrate. These trends and requirements impose ever-increasing challenges on the ability to transfer the circuit pattern from one layer to another layer.

Amorphous silicon (a-Si), polycrystalline silicon (poly-Si), and doped poly-Si (e.g., boron-doped and phosphorous-doped silicon) are widely implemented in the semiconductor industry for different applications. To name a few applications, current multi-patterning techniques use a-Si as a mandrel, which consequently, requires an etch technique to pull the mandrel from high aspect ratio features with very high selectivity towards other films like silicon oxide (SiO₂, or SiOₓ), silicon nitride (SiNₓ), titanium oxide (TiOₓ), titanium nitride (TiN), etc. For replacement metal gate applications, it is necessary to etch poly-Si with very high selectivity to SiO₂, as well as other doped and undoped poly-Si films. Current etch techniques are deficient.

### SUMMARY OF THE INVENTION

Embodiments of the invention relate to a dry non-plasma treatment system and method for treating a substrate, and more particularly to a dry non-plasma treatment system and method for chemical and thermal treatment of a substrate. Additional embodiments include a non-plasma, gas-phase etching of materials and structures on a substrate.

According to one embodiment, a method for the dry removal of a material on a microelectronic workpiece is described. The method includes receiving a workpiece having a surface exposing a target layer composed of silicon selected from the group consisting of amorphous silicon (a-Si), polycrystalline silicon (poly-Si), and doped silicon that fills a trench or via within a retention layer, and selectively removing at least a portion of the target layer from the retention layer. The selective removal includes exposing the surface of the workpiece to a chemical environment containing N, H, and F at a first setpoint temperature to chemically alter a surface region of the target layer, and then, elevating the temperature of the workpiece to a second setpoint temperature to remove the chemically treated surface region of the target layer.

### BRIEF DESCRIPTION OF THE DRAWINGS

In the accompanying drawings:

FIGS. 1A and 1B illustrate a method of dry removing a layer from a high aspect ratio feature on a workpiece according to an embodiment;

FIG. 2 provides a flow chart illustrating a method of dry removing a layer on a substrate according to an embodiment;

FIG. 3 provides a schematic illustration of a dry, non-plasma etching system according to an embodiment; and

FIG. 4 provides a schematic illustration of a workpiece holder according to an embodiment.

### DETAILED DESCRIPTION OF SEVERAL EMBODIMENTS

In the following description, for purposes of explanation and not limitation, specific details are set forth, such as a particular geometry of a processing system, descriptions of various components and processes used therein. However, it should be understood that the invention may be practiced in other embodiments that depart from these specific details.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

As used herein, the term “radiation sensitive material” means and includes photosensitive materials such as photoresists.

As used herein, the term “non-plasma” generally means that plasma is not formed in the space proximate the workpiece being treated. While the products of plasma can be introduced from a remote location to the environment proximate the workpiece being treated, plasma is not actively generated by an electromagnetic field adjacent the workpiece.

“Workpiece” as used herein generically refers to the object being processed in accordance with the invention. The workpiece may include any material portion or structure of a device, particularly a semiconductor or other electronics device, and may, for example, be a base substrate structure, such as a semiconductor wafer or a layer on or overlying a base substrate structure such as a thin film. The workpiece may be a conventional silicon workpiece or other bulk workpiece comprising a layer of semi-conductive material. As used herein, the term “bulk workpiece ” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The workpiece may be doped or undoped. Thus, the workpiece is not intended to be limited to any particular base structure, underlying layer or overlying layer, patterned or un-patterned, but rather, is contemplated to include any such layer or base structure, and any combination of layers and/or base structures. The description below may reference particular types of workpieces, but this is for illustrative purposes only and not limitation.

As noted above, advanced methodologies are required to address the challenges and meet the demands for manipulating materials at sub 30 nm technology nodes. And, as also noted, these methodologies present their own set of challenges, which manifest as issues with etch selectivity, rate, profile control, etc. The ability to successfully integrate advanced device fabrication schemes with highly selective etch processes is paramount to robust devices.

Moreover, the combination of complicated process flows and integration film stacks with the above applications imposes difficult challenges for etch. In particular, highly selective, damage-free processes are required. For example, an isotropic a-Si or poly-Si etch technique with very high selectivity is essential. Currently, a wet etch technique using a mixture of hydrofluoric acid (HF) and nitric acid (HNO₃) is commonly applied for poly-Si etch. However, this wet etch is unable to achieve the desired selectivity to SiO₂. For example, when removing (>80 nm) poly-Si for features with very high aspect ratios (e.g., >5:1), the inventors have observed (significant) pattern collapse as a result of the low etch selectivity to SiO₂. The inventors surmise that the poor selectivity leads to feature under-cutting which makes the feature more susceptible to toppling under fluid stress. Furthermore, hydrophobicity of the wet chemistry prevents etching from features with tight pitch and high aspect ratios (e.g., >15:1). Additionally, in other applications, it may be advantageous to have controllability of the etch rate between various forms of silicon (a-Si, poly-Si, doped Si, etc). While poly-Si removal using plasma etching has been previously explored, the exposure to plasma induces damage to patterns.

According to various embodiments, techniques are described to meet the above mentioned challenges, among others, and provide a dry, selective, and isotropic etch process with little to no pattern damage. As an example and as discussed in greater detail below, silicon etching has been carried out using anhydrous fluorine and nitrogen based gases, e.g. F₂ and NH₃ combined with diluent gases, such as nitrogen (N₂) and argon (Ar). Due to the gas phase nature of this technique, tight pitch and high aspect ratio features do not hinder the etch reactions. The F₂/NH₃ based chemistry has an inherent high selectivity towards films like SiO₂, SiN, silicon-containing antireflective coatings (SiARCs), silicon oxynitride, etc.

The etch processes to be described are considered non-plasma processes, and thus, do not require any direct exposure to plasma. As a result, the risk of plasma induced pattern damage is minimized. Gas phase etch also has the ability to modulate etch rates for various doped poly-Si and a-Si materials. High selectivity assists immensely in preventing pattern damage or pattern collapse. The reaction byproducts for the etch chemistry are expected to includes forms of ammonium fluorosilicate, which is volatile at temperatures above 100° C. under reduced pressure.

The ratio of etch gases to diluent gases (N₂ and Ar) can be carefully controlled and modulated to achieve uniform etch between patterns. Furthermore, the chamber gas pressure enables controllability of the etch rate to account for necessary over-etch and increased throughput. In addition, process parameters, such as temperature and gas concentration, can be carefully modulated to achieve desired etch performance. Furthermore, gas-phase, non-plasma etch chemistry can be derived from or enhanced by chemical species introduced from a remote plasma generator.

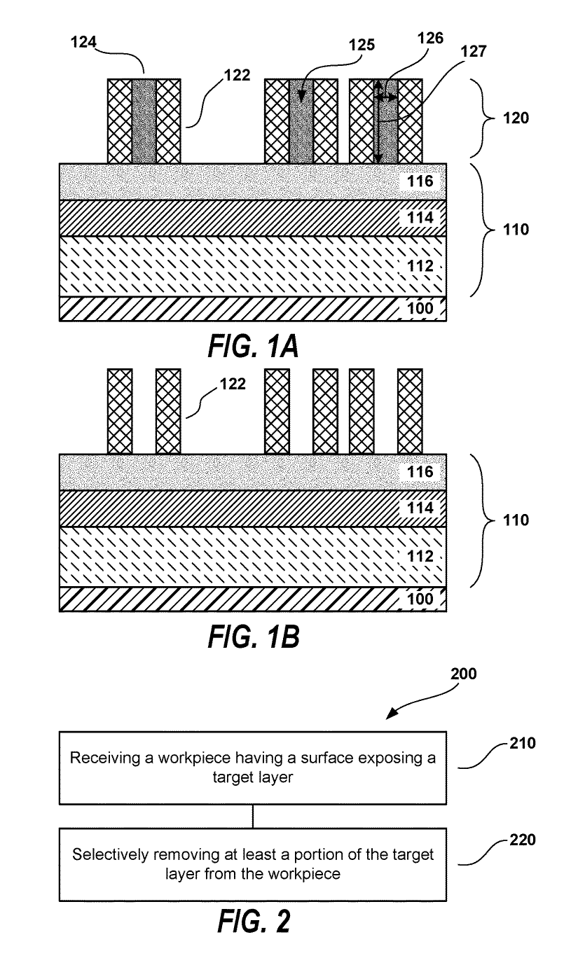

Referring now to the drawings, wherein like reference numerals designate identical or corresponding parts throughout the several views, FIGS. 1A, 1B, and 2 illustrate a method for the dry removal of a material on a microelectronic workpiece according to an embodiment. The method is pictorially illustrated in FIGS. 1A and 1B, and presented by way of a flow chart 200 in FIG. 2. As presented in FIG. 2, the flow chart 200 begins in 210 with receiving a workpiece 100 having a surface exposing a target layer to be at least partially removed.

As shown in FIG. 1A, the workpiece 100 can include a patterned layer 120 overlying a film stack 110, including one or more optional layers 112, 114, 116 to be etched or patterned. The patterned layer 120 can define an open feature pattern overlying one or more additional layers. The workpiece 100 further includes device layers. The device layers can include any thin film or structure on the workpiece into which a pattern is to be transferred, or a target material is to be removed. Furthermore, the patterned layer 120 can include a retention layer 122, and a target layer 124 to be removed.

The target layer 124 can be composed of silicon selected from the group consisting of amorphous silicon (a-Si), polycrystalline silicon (poly-Si), and doped silicon. As shown in FIG. 1A, the target layer 124 fills a trench or via 125 within retention layer 122, the trench or via 125 has a depth (D) 127, a width (W) 126, and an aspect ratio (D/VV). The aspect ratio can be greater than 3, 4, or 5. For some structures, the aspect ratio can be greater than 10, 15, or even 20. The width (W) 126 can be less than 50 nm, 40 nm, 30 nm, or 20 nm. In some applications, the width (W) 126 is less than 10 nm. The retention layer 122 can be composed of material selected from the group consisting of silicon oxide (SiOₓ), silicon nitride (SiN_{y}), silicon oxynitride (SiOₓN_{y}), transition metal oxide (e.g., titanium oxide (TiOₓ)), transition metal nitride (e.g., titanium oxide (TiN_{y})), and silicon-containing organic material having a silicon content ranging from 15% by weight to 50% by weight silicon.

As an example, the patterned layer 120 in FIG. 1A can include a spacer layer surrounding a mandrel layer used in multi-patterning schemes. Alternatively, for example, the patterned layer 120 in FIG. 1A can include a dummy silicon layer filling a region to be replaced with an advanced gate structure, such as a metal gate structure.

The workpiece 100 can include a bulk silicon substrate, a single crystal silicon (doped or un-doped) substrate, a semiconductor-on-insulator (SOI) substrate, or any other semiconductor substrate containing, for example, Si, SiC, SiGe, SiGeC, Ge, GaAs, InAs, InP, as well as other III/V or II/VI compound semiconductors, or any combination thereof (Groups II, Ill, V, VI refer to the classical or old IUPAC notation in the Periodic Table of Elements; according to the revised or new IUPAC notation, these Groups would refer to Groups 2, 13, 15, 16, respectively). The workpiece 100 can be of any size, for example, a 200 mm (millimeter) substrate, a 300 mm substrate, a 450 mm substrate, or an even larger substrate. The device layers can include any film or device structure into which a pattern can be transferred.

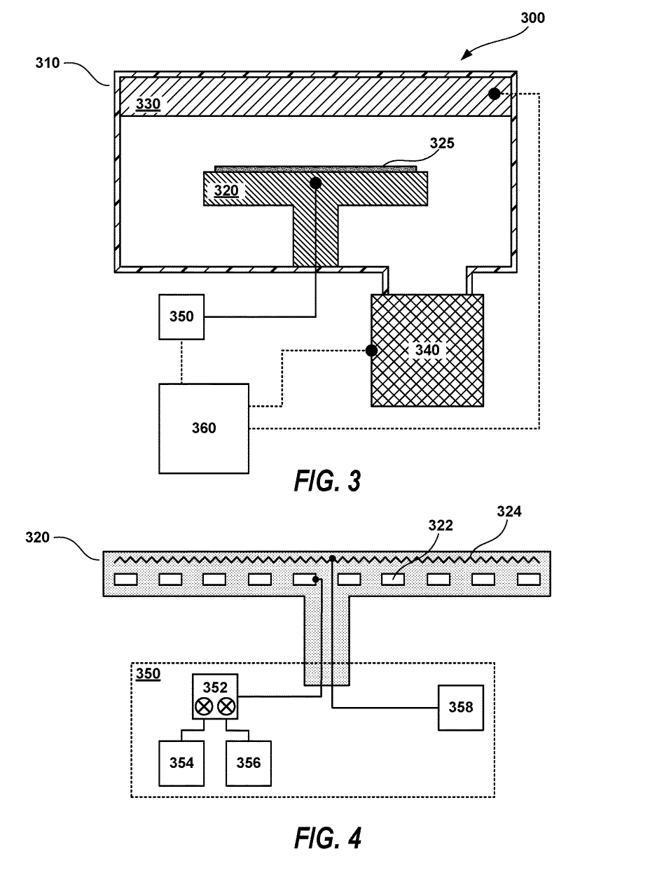

In 220, at least a portion of the target layer 124 is selectively removed from the workpiece 100. For example, the target layer 124 can be selectively removed relative to the retention layer 122 and layer 116 of film stack 110. The selective removal can be performed by placing the workpiece 100 in a single chamber, dry, non-plasma etch system, such as the system to be described in FIG. 3 or the system described in U.S. Pat. No. 7,718,032, entitled “Dry non-plasma treatment system and method of using”, or a tandem chamber, dry, non-plasma etch system, such as the system described in U.S. Pat. No. 7,029,536, entitled “Processing system and method for treating a substrate” or U.S. Pat. No. 8,303,716, entitled “High throughput processing system for chemical treatment and thermal treatment and method of operating”; the entire contents of which are herein incorporated by reference.

According to one embodiment, the selective removal is performed by exposing the surface of the workpiece to a chemical environment containing N, H, and F at a first setpoint temperature to chemically alter a surface region of the target layer, and then, elevating the temperature of the workpiece to a second setpoint temperature to remove the chemically treated surface region of the target layer. The target layer 124 can include a layer composed silicon selected from the group consisting of amorphous silicon (a-Si), polycrystalline silicon (poly-Si), and doped silicon.

During the exposing, select surfaces of the workpiece, including exposed surfaces of the target layer 124, are chemically treated by the gas-phase chemical environment. A specific material can be targeted and a pre-determined depth can be achieved by selecting various process parameters, including the processing pressure for the chemical environment, the temperature of the workpiece, the temperature of the workpiece holder, the temperature of other chamber components, the composition of the chemical environment, and the absolute and relative flow rates of the gas-phase constituents into the chamber. Upon elevation of the temperature of the workpiece, the chemically altered region of select surfaces of the target layer 124 is volatilized and removed.

As described above the temperature of the workpiece holder, or workpiece, can be selected to selectively remove one material relative to another. In one example, to selectively remove a layer composed of a-Si, poly-Si, or doped silicon (doped a-Si, or doped poly-Si), relative to silicon oxide, silicon nitride, silicon oxynitride, transition metal oxide (e.g., titanium oxide), transition metal nitride (e.g., titantium nitride), silicon-containing organic material, and organic materials, the first temperature of the workpiece holder, or workpiece, can range from 50 degrees C. to 100 degrees C., or 60 degrees C. to 90 degrees C., or preferably from 70 degrees C. to 90 degrees C., or more preferably from 80 degrees C. to 90 degrees C.

The chemical environment can contain HF, NF₃, F₂, NH₃, N₂, or H₂, or a combination of two or more thereof. In one embodiment, the chemical environment contains anhydrous F₂ and ammonia (NH₃). The chemical environment can further contain a noble element. In other embodiments, the chemical environment can contain an excited specie, a radical specie, or a metastable specie, or any combination of two or more thereof. For example, the dry, non-plasma etch chamber includes a remote plasma generator or remote radical generator arranged to supply the dry, non-plasma etch chamber with excited, radical or metastable specie of F, N, or H. The processing pressure can range from 500 mTorr to 2 Torr.

Thereafter, the targeted chemically altered surface layers are desorbed by elevating the temperature from the first temperature to the second temperature, which may take place in the same chamber or a separate chamber. The second temperature can range from 100 degrees C. to 225 degrees C., or preferably, the second temperature ranges from 160 degrees C. to 200 degrees C., or more preferably, the second temperature ranges from 170 degrees C. to 195 degrees C.

In one example, the inventors have demonstrated the selective removal of a target layer composed of a poly-Si from a trench within silicon nitride overlying silicon oxide. The trench had a width of about 5 nm and a depth of about 100 nm. Poly-Si can be completely removed with little to no pattern lift-off or damage, and oxide layer loss. As an example, chemical treatment was performed in a chemical treatment chamber, thermal treatment was performed in a thermal treatment chamber, and the chemical-thermal treatment cycle was repeated. The first setpoint temperature was set to 80-85 degrees C., and the second setpoint temperature was set to 170-195 degrees C. During chemical treatment, the workpiece was exposed to a mixture of anhydrous fluorine, ammonia, argon, and nitrogen.

Furthermore, the steps of exposing and elevating can be alternatingly and sequentially performed. From one step to the next, or one cycle to the next, any one or more of the process parameters, including the processing pressure for the chemical environment, the temperature of the workpiece, the temperature of the workpiece holder, the temperature of other chamber components, the composition of the chemical environment, and the absolute and relative flow rates of the gas-phase constituents into the chamber, can be adjusted.

According to another embodiment, the workpiece 100 is placed on a workpiece holder in a single chamber, dry, non-plasma etch system, such as the system described in FIG. 3. The single chamber, dry, non-plasma etch system is operated to perform the following: (1) exposing the surface of the workpiece to a chemical environment at a first setpoint temperature in the range of 35 degrees C. to 100 degrees C. to chemically alter a surface region of the target layer, and (2) then, elevating the temperature of the workpiece to a second setpoint temperature at or above 100 degrees C. to remove the chemically treated surface region of the target layer. The first setpoint temperature can range from 35 degrees C. to 100 degrees C., or 70 degrees C. to 90 degrees C., and the second setpoint temperature can range from 110 degrees C. to 225 degrees C.

The first setpoint temperature can be established by flowing a heat transfer fluid through the workpiece holder at a first fluid setpoint temperature. The second setpoint temperature can be established by flowing the heat transfer fluid through the workpiece holder at a second fluid setpoint temperature. In addition to flowing the heat transfer fluid through the workpiece holder at the second fluid setpoint temperature, the workpiece holder can be heated by coupling electrical power to at least one resistive heating element embedded within the workpiece holder. Alternatively, in addition to flowing the heat transfer fluid through the workpiece holder at the second fluid setpoint temperature, heating the workpiece holder using at least one other heat source separate from the workpiece holder.

According to another embodiment, a system 300 for the dry removal of a material on a microelectronic workpiece 325 is shown in FIG. 3. The system 300 includes a process chamber 310 for processing workpiece 325 in a non-plasma, vacuum environment, a workpiece holder 320 arranged within the process chamber 310, and configured to support the workpiece 325, a temperature control system 350 coupled to the workpiece holder 320, and configured to control the temperature of the workpiece holder 320 at two or more setpoint temperatures, a gas distribution system 330 coupled to the process chamber 310, and arranged to supply one or more process gases into the process chamber 310, and a controller 360 operably coupled to the temperature control system 350, and configured to control the temperature of the workpiece holder 320 ranging from 35 degrees C. to 250 degrees C. For example, the temperature control system 350 can be configured to control the temperature of the workpiece holder 320 at a first setpoint temperature in the range of 35 degrees C. to 100 degrees C., and adjust and control the temperature of the workpiece holder 320 at a second setpoint temperature at or above 100 degrees C. Alternatively, for example, the temperature control system 350 can be configured to control the temperature of the workpiece holder 320 at a first setpoint temperature in the range of 10 degrees C. to 100 degrees C., and adjust and control the temperature of the workpiece holder 320 at a second setpoint temperature at or above 100 degrees C.

The process chamber 310 can include a vacuum pump 340 to evacuate process gases from process chamber 310. The process chamber 310 can further include a remote plasma generator or remote radical generator arranged to supply the process chamber with excited, radical or metastable species, or combinations thereof.

Gas distribution system 330 can include a showerhead gas injection system having a gas distribution assembly, and one or more gas distribution plates or conduits coupled to the gas distribution assembly and configured to form one or more gas distribution plenums or supply lines. Although not shown, the one or more gas distribution plenums may comprise one or more gas distribution baffle plates. The one or more gas distribution plates further comprise one or more gas distribution orifices to distribute a process gas from the one or more gas distribution plenums to the process chamber 310. Additionally, one or more gas supply lines may be coupled to the one or more gas distribution plenums through, for example, the gas distribution assembly in order to supply a process gas comprising one or more gases. Process gases can be introduced together as a single flow, or independently as separate flows.

Gas distribution system 330 can further include a branching gas distribution network designed to reduce or minimize gas distribution volume. The branching network can remove plenums, or minimize the volume of gas plenums, and shorten the gas distribution length from gas valve to process chamber, while effectively distributing the process gas across the diameter of the workpiece 325. In doing so, gases can be switched more rapidly, and the composition of the chemical environment can be changed more effectively.

The volume of the process chamber 310 defining the chemical environment, to which the workpiece 325 is exposed, can be reduced or minimized in order to reduce or minimize the residence time or time required to evacuate, displace, and replace one chemical environment with another chemical environment. The time to displace the chemical environment in the process chamber 310 can be estimated as the ratio of the process chamber volume to the pumping speed delivered to the process chamber volume by the vacuum pump 340.

Workpiece holder 320 can provide several operational functions for thermally controlling and processing workpiece 325. The workpiece holder 320 includes one or more temperature control elements configured to adjust and/or elevate a temperature of the workpiece 320.

As shown in FIG. 4, workpiece holder 320 can include at least one fluid channel 322 to allow flow of a heat transfer fluid there through and alter a temperature of the workpiece holder 320. Workpiece holder 320 can further include at least one resistive heating element 324. Multi-zone channels and/or heating elements can be used to adjust and control the spatial uniformity of heating and cooling of workpiece 325. For example, the at least one resistive heating element 324 can include a central-zone heating element and an edge-zone heating element. Additionally, for example, the at least one fluid channel 322 can include a central-zone fluid channel and an edge-zone fluid channel. At temperatures above 200 to 250 degrees C., other heating systems can be used, including infrared (IR) heating, such as lamp heating, etc.

A power source 358 is coupled to the at least one resistive heating element 324 to supply electrical current. The power source 358 can include a direct current (DC) power source or an alternating current (AC) power source. Furthermore, the at least one resistive heating element 324 can be connected in series or connected in parallel.

The at least one heating element 324 can, for example, include a resistive heater element fabricated from carbon, tungsten, nickel-chromium alloy, aluminum-iron alloy, aluminum nitride, etc. Examples of commercially available materials to fabricate resistive heating elements include Kanthal, Nikrothal, Akrothal, which are registered trademark names for metal alloys produced by Kanthal Corporation of Bethel, Conn. The Kanthal family includes ferritic alloys (FeCrAl) and the Nikrothal family includes austenitic alloys (NiCr, NiCrFe). According to one example, each of the at least one resistive heating element 324 can include a heating element, commercially available from Watlow Electric Manufacturing Company (12001 Lackland Road, St. Louis, Mo. 63146). Alternatively, or in addition, cooling elements can be employed in any of the embodiments.

A heat transfer fluid distribution manifold 352 is arranged to pump and monitor the flow of heat transfer fluid through the one or more fluid channels 322. The heat transfer fluid distribution manifold 352 can draw heat transfer fluid from a first heat transfer fluid supply bath 354 at a first heat transfer fluid temperature and/or a second heat transfer fluid supply bath 356 at a second heat transfer fluid temperature. Manifold 352 can mix heat transfer fluid from the first and second fluid baths 354, 356 to achieve an intermediate temperature. Furthermore, the heat transfer fluid distribution manifold 352 can include a pump, a valve assembly, a heater, a cooler, and a fluid temperature sensor to controllably supply, distribute, and mix a heat transfer fluid at a predetermined temperature.

In an alternative embodiment, the temperature control system 360 can include a hot wall in close proximity to the work piece holder 320. The workpiece holder 320 can further include a workpiece clamping system configured to clamp the workpiece to the workpiece holder, and a backside gas supply system configured to supply a heat transfer gas to the backside of the workpiece.

The heat transfer fluid can include a high temperature fluid having a boiling point exceeding 200 degrees C. For example, the heat transfer fluid can include Fluorinert™ FC40 (having a temperature range of −57 to 165 dgrees C.), or Fluorinert™ FC70 (having a temperature range of −25 to 215 dgrees C.), commercially available from 3M.

Workpiece holder 320 can be monitored using a temperature sensing device, such as a thermocouple (e.g. a K-type thermocouple, Pt sensor, etc.) or optical device. Furthermore, the substrate holder temperature control system 350 may utilize the temperature measurement as feedback to the workpiece holder 320 in order to control the temperature of workpiece holder 320. For example, at least one of a fluid flow rate, a fluid temperature, a heat transfer gas type, a heat transfer gas pressure, a clamping force, a resistive heater element current or voltage, a thermoelectric device current or polarity, etc. may be adjusted in order to affect a change in the temperature of workpiece holder 320 and/or the temperature of the workpiece 325.

As noted above, controller 360 is operably coupled to the temperature control system 350, and configured to control the temperature of various components in system 300, including the workpiece holder 320, at temperatures ranging from 10 degrees C. to 250 degrees C., or 35 degrees C. to 250 degrees C., or 50 degrees C. to 250 degrees C. For example, under instruction of controller 360, the temperature control system 350 can be configured to control the temperature of the workpiece holder 320 at a first setpoint temperature in the range of 35 degrees C. to 100 degrees C., and adjust and control the temperature of the workpiece holder 320 at a second setpoint temperature at or above 100 degrees C. (see process recipes described above). The temperature control system 350 can obtain temperature information from one or more temperature sensors arranged to measure the temperature of the workpiece holder 320, the workpiece 325, the chamber wall of the process chamber 310, or the temperature of the gas distribution system 330, among others, and utilize the temperature information to controllably adjust these temperatures.

As an example, when changing the temperature of the workpiece holder 320 from the first setpoint temperature, in the range of 35 degrees C. to 100 degrees C., to the second setpoint temperature, at or above 100 degrees C., the fluid temperature of the heat transfer temperature can be adjusted rapidly by changing the ratio of heat transfer fluid drawn from the heat transfer fluid supply baths 354, 356. Once within a predetermined range of the targeted second setpoint temperature, the at least one resistive heating element can be utilized to accurately control the setpoint temperature. The workpiece holder 320 can be designed to have a relatively low thermal mass. For example, the thickness of the holder and material composition of the holder can be designed to reduce or minimize the thermal mass of the holder. Furthermore, the at least one fluid channel 322, including the fluid conduits supplying heat transfer fluid to the at least one fluid channel 322, can be designed to have low volume in order to change fluid temperature rapidly. For example, the length and diameter of the fluid channels and conduits can be designed to reduce or minimize volume (i.e., reduce the time necessary to displace fluid of one temperature, and replace it with fluid of another temperature).

Other chamber components of process chamber 310, including chamber walls, the gas distribution system 330, etc., can include heating and/or cooling elements to control the temperature thereof. For example, the chamber wall temperature of the process chamber 310 and the temperature of at least a portion of the gas distribution system can be controlled to a temperature up to 150 degrees C., or within the range 50 degrees C. to 150 degrees C. (preferably, 70 degrees C. to 110 degrees C.).

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method for the dry removal of a material on a microelectronic workpiece, comprising:
receiving a workpiece having a surface exposing a target layer composed of silicon selected from the group consisting of amorphous silicon (a-Si), polycrystalline silicon (poly-Si), and doped silicon, wherein the target layer fills a trench or via within a retention layer, the trench or via having a depth (D), a width (W), and an aspect ratio (D/VV) equal to or greater than 5, and wherein the retention layer is selected from the group consisting of silicon oxide (SiOₓ), silicon nitride (SiN_{y}), silicon oxynitride (SiOₓN_{y}), transition metal oxide (<TM>Oₓ), transition metal nitride (<TM>N_{y}), and silicon-containing organic material having a silicon content ranging from 15% by weight to 50% by weight silicon; and
selectively removing at least a portion of the target layer from the trench or via within the retention layer by performing the following:
exposing the surface of the workpiece to a chemical environment containing N, H, and F at a first setpoint temperature to chemically alter a surface region of the target layer, and
then, elevating the temperature of the workpiece to a second setpoint temperature to remove the chemically treated surface region of the target layer.

2. The method of claim 1, further comprising:
placing the workpiece in a dry, non-plasma etch system; and
operating the dry, non-plasma etch system to perform the selectively removing in a single chamber.

3. The method of claim 1, further comprising:
placing the workpiece in a dry, non-plasma etch system; and
operating the dry, non-plasma etch system to perform the selectively removing in a tandem chamber arrangement, wherein the exposing the surface of the workpiece to a chemical environment is performed in a chemical treatment chamber, and the elevating the temperature of the workpiece to a second setpoint temperature is performed in a separate thermal treatment chamber.

4. The method of claim 1, wherein the first temperature is less than 100 degrees C., and the second temperature is greater than 100 degrees C.

5. The method of claim 1, wherein the first temperature ranges from 35 degrees C. to 100 degrees C., and the second temperature ranges from 100 degrees C. to 225 degrees C.

6. The method of claim 1, wherein the first temperature ranges from 80 degrees C. to 90 degrees C., and the second temperature ranges from 170 degrees C. to 200 degrees C.

7. The method of claim 1, wherein steps of exposing and elevating are performed at a processing pressure ranging from 500mTorr to 2 Torr.

8. The method of claim 1, wherein the steps of exposing and elevating are alternatingly and sequentially performed.

9. The method of claim 1, wherein the chemical environment contains HF, NF₃, F₂, NH₃, N₂, or H₂, or a combination of two or more thereof.

10. The method of claim 9, wherein the chemical environment contains anhydrous fluorine (F₂) and ammonia (NH₃).

11. The method of claim 9, wherein the chemical environment further contains a noble element, or nitrogen (N₂), or both a noble element and nitrogen.

12. The method of claim 1, wherein the chemical environment contains an excited specie, a radical specie, or a metastable specie, or any combination of two or more thereof.

13. The method of claim 1, wherein the dry, non-plasma etch chamber includes a remote plasma generator or remote radical generator arranged to supply the dry, non-plasma etch chamber with excited, radical or metastable specie of F, N, or H.

14. The method of claim 10, wherein the target layer includes poly-Si filling a trench or via extending through a layer of silicon nitride in contact with silicon oxide.

15. The method of claim 14, wherein the width of the trench or via is less than 10 nm.

16. The method of claim 15, wherein the aspect ratio exceeds 15.

17. The method of claim 1, wherein the aspect ratio exceeds 10.

18. The method of claim 2, further comprising:
locating the workpiece on a workpiece holder; and
establishing the first temperature by flowing a heat transfer fluid through the workpiece holder at a first fluid setpoint temperature.

19. The method of claim 18, further comprising:
changing the first fluid setpoint temperature to a second fluid setpoint temperature; and
flowing the heat transfer fluid at the second fluid setpoint temperature through the workpiece holder.

20. The method of claim 19, further comprising:
while flowing the heat transfer fluid at the second fluid setpoint temperature, heating the workpiece by coupling power to one or more resistive heating elements embedded within the workpiece holder.
